(19) United States
(12) Patent Application Publication
(10) Pub. No.: US 2023/0054165 A1
(43) Pub. Date: Feb. 23, 2023

(54) POINT-OF-USE ULTRASONIC HOMOGENIZER FOR CMP SLURRY AGGLOMERATION REDUCTION

(71) Applicant: Applied Materials, Inc., Santa Clara, CA (US)

(72) Inventors: Chih Chung Chou, San Jose, CA (US); Haosheng Wu, Fremont, CA (US); Jianshe Tang, San Jose, CA (US); Shou-Sung Chang, Mountain View, CA (US); Brian J. Brown, Palo Alto, CA (US); Chad Pollard, San Jose, CA (US); Hari N. Soundararajan, Sunnyvale, CA (US)

(73) Assignee: Applied Materials, Inc., Santa Clara, CA (US)

(21) Appl. No.: 17/405,898

(22) Filed: Aug. 18, 2021

(51) Int. Cl. B24B 37/34; H01L 21/306; H01L 21/66; B06B 1/06; B01F 11/02; B01F 15/06

(52) U.S. Cl. CPC B24B 37/34; H01L 21/30625; H01L 22/20; B06B 1/0622; B01F 11/0241; B01F 15/06; B06B 2201/77; B01F 2015/062; B01F 2015/061; B01F 2215/0096

(57) ABSTRACT

Exemplary slurry delivery assemblies may include a slurry fluid source. The assemblies may include a flurry delivery lumen having a lumen inlet and a lumen outlet. The lumen inlet may be fluidly coupled with an output of the slurry fluid source. The assemblies may include a deagglomeration tube fluidly coupled with the lumen outlet. The deagglomeration tube may include a tube inlet and a tube outlet. The assemblies may include one or more ultrasonic transducers coupled with the deagglomeration tube.

### TECHNICAL FIELD

The present technology relates to semiconductor systems, processes, and equipment. More specifically, the present technology relates to the polishing of films deposited on a substrate.

### BACKGROUND

An integrated circuit is typically formed on a substrate by the sequential deposition of conductive, semiconductive, and/or insulative layers on a silicon wafer. A variety of fabrication processes use the planarization of a layer on the substrate between processing steps. For example, for certain applications, e.g., polishing of a metal layer to form vias, plugs, and/or lines in the trenches of a patterned layer, an overlying layer is planarized until the top surface of a patterned layer is exposed. In other applications, e.g., planarization of a dielectric layer for photolithography, an overlying layer is polished until a desired thickness remains over the underlying layer.

Chemical mechanical polishing (CMP) is one common method of planarization. This planarization method typically requires that the substrate be mounted on a carrier or polishing head. The exposed surface of the substrate is typically placed against a rotating polishing pad. The carrier head provides a controllable load on the substrate to push it against the polishing pad. Abrasive polishing slurry is typically supplied to the surface of the polishing pad.

One problem in CMP is that over time the abrasive particles within the polishing slurry may agglomerate to form more coarse particles. These coarse particles may unevenly polish the surface of the film. Additionally, the coarse particles may scratch the film surface.

Thus, there is a need for improved systems and methods that can be used to more uniformly polish substrates. These and other needs are addressed by the present technology.

### SUMMARY

Exemplary slurry delivery assemblies may include a slurry fluid source. The assemblies may include a flurry delivery lumen having a lumen inlet and a lumen outlet. The lumen inlet may be fluidly coupled with an output of the slurry fluid source. The assemblies may include a deagglomeration tube fluidly coupled with the lumen outlet. The deagglomeration tube may include a tube inlet and a tube outlet. The assemblies may include one or more ultrasonic transducers coupled with the deagglomeration tube.

In some embodiments, the one or more ultrasonic transducers may include piezoelectric transducers. The one or more ultrasonic transducers may be positioned against an outer surface of the deagglomeration tube. The assemblies may include an adapter interposed between the outer surface of the deagglomeration tube and the one or more ultrasonic transducers. The one or more ultrasonic transducers may be spaced apart evenly along length of deagglomeration tube.

The one or more ultrasonic transducers may be positioned on multiple sides of the deagglomeration tube. The assemblies may include a support arm that is coupled with the deagglomeration tube. An internal end of the deagglomeration tube proximate the tube outlet may be funnel-shaped.

Some embodiments of the present technology may encompass slurry delivery assemblies. The assemblies may include a deagglomeration tube. The deagglomeration tube may include an inlet. The deagglomeration tube may include an outlet. The deagglomeration tube may include a medial region disposed between the inlet and the outlet. The medial region may have a greater diameter than the inlet and the outlet. The assemblies may include one or more ultrasonic transducers coupled with the deagglomeration tube.

In some embodiments, the assemblies may include a wave transmission rod having a proximal end and a distal end. The proximal end may be coupled with the one or more ultrasonic transducers and the distal end may protrude into an interior of the medial region of the deagglomeration tube. The wave transmission rod may extend at least partially along a length of the medial region of the deagglomeration tube. The assemblies may include a temperature control mechanism disposed proximate the deagglomeration tube. The temperature control mechanism may include one or both of a heating device and a cooling device. The assemblies may include a thermocouple that is coupled with the medial region of the deagglomeration tube. The thermocouple may be disposed within an interior of the medial region of the deagglomeration tube. The assemblies may include a delivery spout coupled with the outlet.

Some embodiments of the present technology may encompass methods of polishing a substrate. The methods may include flowing a polishing slurry into a deagglomeration tube. The methods may include actuating one or more ultrasonic transducers that are coupled with the deagglomeration tube while the polishing slurry is flowed through the deagglomeration tube. The methods may include delivering the polishing slurry to a polishing pad. The methods may include polishing a substrate atop the polishing pad.

In some embodiments, the methods may include monitoring a temperature of one or both of the deagglomeration tube and the polishing slurry. The methods may include adjusting a temperature control mechanism positioned proximate the deagglomeration tube based on the temperature. The deagglomeration tube may include quartz.

Such technology may provide numerous benefits over conventional systems and techniques. For example, the slurry delivery assemblies described herein may generate ultrasonic waves to deagglomerate or otherwise break up masses of abrasive particles within the polishing slurry prior to delivering the polishing slurry to a polishing pad. Such deagglomeration may ensure that the abrasive particles reaching the polishing pad are of a proper size to effectively and uniformly polish a film layer on a wafer. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary polishing system according to some embodiments of the present technology.

FIG. 2 shows a schematic partial cross-sectional view of an exemplary slurry delivery assembly according to some embodiments of the present technology.

FIG. 3 shows a schematic partial cross-sectional view of an exemplary slurry delivery assembly according to some embodiments of the present technology.

FIG. 3A shows a schematic partial cross-sectional view of the slurry delivery assembly of FIG. 3 according to some embodiments of the present technology.

FIG. 3B a schematic partial cross-sectional view of the slurry delivery assembly of FIG. 3 according to some embodiments of the present technology.

FIG. 4 shows a schematic partial cross-sectional view of an exemplary slurry delivery assembly according to some embodiments of the present technology.

FIG. 5 is a flowchart of an exemplary method of polishing a substrate according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In conventional chemical mechanical polishing (CMP) operations an abrasive slurry is typically delivered to a polishing pad. Abrasive particles within the slurry are used to remove and polish a surface of films deposited on a substrate. The abrasive particles often have sizes that are on the order of tens of nanometers. The abrasive particles may have a tendency to agglomerate and/or otherwise collect to form larger particles. These larger particles may cause uneven polishing and/or scratching of the film layers. Conventional CMP systems may attempt to prevent larger particles from reaching the polishing pad by incorporating filters in the slurry delivery equipment. However, the filters are typically positioned well upstream of a delivery spout. This positioning may leave a significant distance after the filter in which particles may agglomerate prior to being dispensed onto the polishing pad.

The present technology overcomes these issues with conventional polishing systems by providing ultrasonic transducers proximate a dispensing spout of the slurry delivery mechanism. The ultrasonic transducers may emit sound waves that vibrate and/or otherwise agitate the abrasive particles to deagglomerate and/or otherwise break up any larger particles within the polishing slurry. Embodiments may position the ultrasonic transducers proximate a deagglomeration tube that has a greater cross-section than an input lumen, which may slow down the flow of the polishing slurry to ensure that the polishing slurry is exposed to a sufficient amount of waves to break up the larger particles. Temperature control mechanisms may be included to ensure that the slurry is maintained within a desired temperature range prior to being dispensed onto the polishing pad. Embodiments may ensure that the polishing slurry is delivered with sufficiently small abrasive particles and at a desired temperature to help more effectively polish the film surface.

Although the remaining disclosure will routinely identify specific slurry delivery mechanism utilizing the disclosed technology, it will be readily understood that the systems and methods are equally applicable to a variety of other semiconductor processing operations and systems. Accordingly, the technology should not be considered to be so limited as for use with the described polishing systems or processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems, along with any number of modifications, some of which will be noted below.

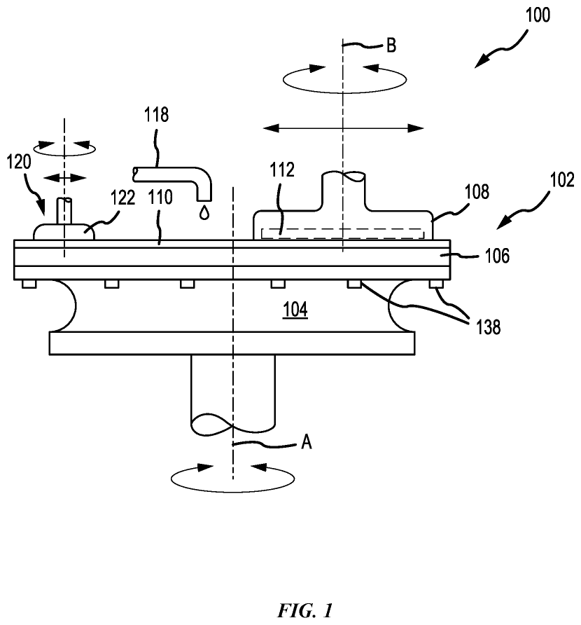

FIG. 1 shows a schematic cross-sectional view of an exemplary polishing system 100 according to some embodiments of the present technology. Polishing system 100 includes a platen assembly 102, which includes a lower platen 104 and an upper platen 106. Lower platen 104 may define an interior volume or cavity through which connections can be made, as well as in which may be included end-point detection equipment or other sensors or devices, such as eddy current sensors, optical sensors, or other components for monitoring polishing operations or components. For example, and as described further below, fluid couplings may be formed with lines extending through the lower platen 104, and which may access upper platen 106 through a backside of the upper platen. Platen assembly 102 may include a polishing pad 110 mounted on a first surface of the upper platen. A substrate carrier 108, or carrier head, may be disposed above the polishing pad 110 and may face the polishing pad 110. The platen assembly 102 may be rotatable about an axis A, while the substrate carrier 108 may be rotatable about an axis B. The substrate carrier may also be configured to sweep back and forth from an inner radius to an outer radius along the platen assembly, which may, in part, reduce uneven wear of the surface of the polishing pad 110. The polishing system 100 may also include a fluid delivery arm 118 positioned above the polishing pad 110, and which may be used to deliver polishing fluids, such as a polishing slurry, onto the polishing pad 110. Additionally, a pad conditioning assembly 120 may be disposed above the polishing pad 110, and may face the polishing pad 110.

In some embodiments of performing a chemical-mechanical polishing process, the rotating and/or sweeping substrate carrier 108 may exert a downforce against a substrate 112, which is shown in phantom and may be disposed within or coupled with the substrate carrier. The downward force applied may depress a material surface of the substrate 112 against the polishing pad 110 as the polishing pad 110 rotates about a central axis of the platen assembly. The interaction of the substrate 112 against the polishing pad 110 may occur in the presence of one or more polishing fluids delivered by the fluid delivery arm 118. A typical polishing fluid may include a slurry formed of an aqueous solution in which abrasive particles may be suspended. Often, the polishing fluid contains a pH adjuster and other chemically active components, such as an oxidizing agent, which may enable chemical mechanical polishing of the material surface of the substrate 112.

The pad conditioning assembly 120 may be operated to apply a fixed abrasive conditioning disk 122 against the surface of the polishing pad 110, which may be rotated as previously noted. The conditioning disk may be operated against the pad prior to, subsequent, or during polishing of the substrate 112. Conditioning the polishing pad 110 with the conditioning disk 122 may maintain the polishing pad 110 in a desired condition by abrading, rejuvenating, and removing polish byproducts and other debris from the polishing surface of the polishing pad 110. Upper platen 106 may be disposed on a mounting surface of the lower platen 104, and may be coupled with the lower platen 104 using a plurality of fasteners 138, such as extending through an annular flange shaped portion of the lower platen 104.

The polishing platen assembly 102, and thus the upper platen 106, may be suitably sized for any desired polishing system, and may be sized for a substrate of any diameter, including 200 mm, 300 mm, 450 mm, or greater. For example, a polishing platen assembly configured to polish 300 mm diameter substrates, may be characterized by a diameter of more than about 300 mm, such as between about 500 mm and about 1000 mm, or more than about 500 mm. The platen may be adjusted in diameter to accommodate substrates characterized by a larger or smaller diameter, or for a polishing platen 106 sized for concurrent polishing of multiple substrates. The upper platen 106 may be characterized by a thickness of between about 20 mm and about 150 mm, and may be characterized by a thickness of less than or about 100 mm, such as less than or about 80 mm, less than or about 60 mm, less than or about 40 mm, or less. In some embodiments, a ratio of a diameter to a thickness of the polishing platen 106 may be greater than or about 3:1, greater than or about 5:1, greater than or about 10:1, greater than or about 15:1, greater than or about 20:1, greater than or about 25:1, greater than or about 30:1, greater than or about 40:1, greater than or about 50:1, or more.

The upper platen and/or the lower platen may be formed of a suitably rigid, light-weight, and polishing fluid corrosion-resistant material, such as aluminum, an aluminum alloy, or stainless steel, although any number of materials may be used. Polishing pad 110 may be formed of any number of materials, including polymeric materials, such as polyurethane, a polycarbonate, fluoropolymers, polytetrafluoroethylene polyphenylene sulfide, or combinations of any of these or other materials. Additional materials may be or include open or closed cell foamed polymers, elastomers, felt, impregnated felt, plastics, or any other materials that may be compatible with the processing chemistries. It is to be understood that polishing system 100 is included to provide suitable reference to components discussed below, which may be incorporated in system 100, although the description of polishing system 100 is not intended to limit the present technology in any way, as embodiments of the present technology may be incorporated in any number of polishing systems that may benefit from the components and/or capabilities as described further below.

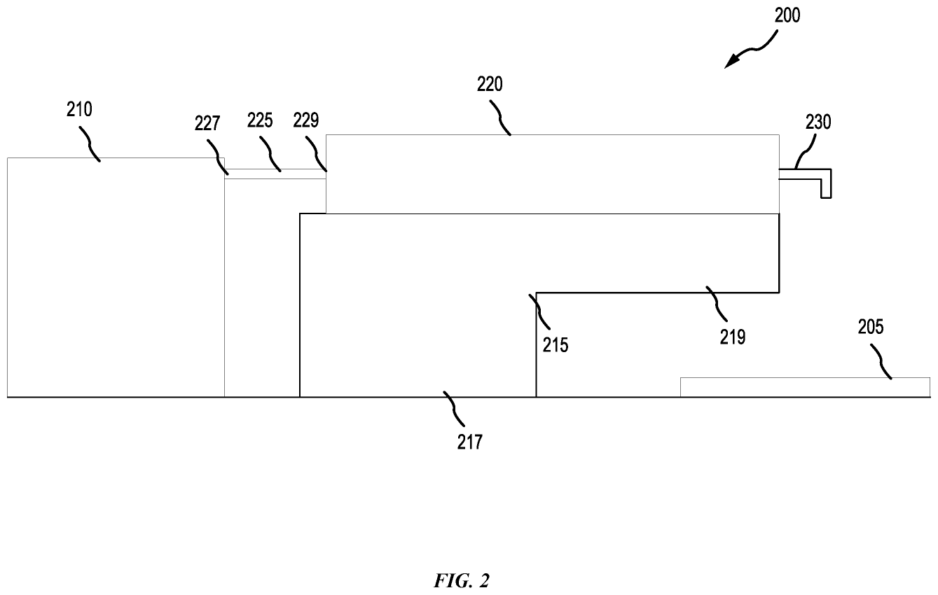

FIG. 2 illustrates a schematic cross-sectional view of an exemplary slurry delivery assembly 200 according to some embodiments of the present technology. The assembly 200 may be used to delivery abrasive polishing slurry to a polishing pad 205, which may be similar to polishing pad 110 in some embodiments. Assembly 200 may show a partial view of the components being discussed and that may be incorporated in a polishing system, similar to polishing system 100. Assembly 200 may include a slurry fluid source 210, which may include a reservoir that holds a volume of polishing slurry. The polishing slurry may include abrasive particles that provide grit that helps the polishing pad 205 to polish the film on the substrate. For example, the slurry may include a nano-sized abrasive powder dispersed in a chemically reactive solution, which may enable the solution to chemically etch and soften the film while the abrasive particles mechanically abrade and/or otherwise remove a portion of the film to planarize and/or otherwise alter a surface of a substrate. The abrasive particles have sizes that are often between about 10 nm and 250 nm, although other sizes of abrasive particles may be used in various embodiments. Slurry fluid source 210 may also include a pump and/or other positive pressure source that may be used to selectively flow the polishing slurry to the polishing pad 205. The polishing slurry may be delivered continuously and/or intermittently during a given polishing operation.

Assembly 200 may include a support arm 215 that may support a delivery spout 230 at a position that is above a portion of the polishing pad 205. For example, a base 217 of the support arm 215 may be positioned radially outward of the polishing pad 205, with an upper portion 219 of the support arm 215 extending outward over a portion of the polishing pad 205 such that a volume of polishing slurry may be delivered to a top surface of the polishing pad 205 via the delivery spout 230.

Assembly 200 may include a deagglomeration tube 220, which may be positioned downstream of the slurry fluid source 210. For example, the deagglomeration tube 220 may be mounted on and/or otherwise coupled with the support arm 215. In some embodiments, the deagglomeration tube 220 may be formed as part of the support arm 215. A fluid delivery lumen 225 may extend between the slurry fluid source 210 and the deagglomeration tube 220 and may fluidly couple the deagglomeration tube 220 with the slurry fluid source 210. For example, an inlet 227 of the fluid delivery lumen 225 may be coupled with an output of the slurry fluid source 210, while an outlet 229 of the fluid delivery lumen 225 may be coupled with an inlet of the deagglomeration tube 220. This may enable a volume of polishing slurry to be flowed into the deagglomeration tube 220 via the fluid delivery lumen 225 prior to being delivered to the polishing pad 205. The polishing slurry may be delivered to the polishing pad 205 via the delivery spout 230, which may be coupled with an outlet of the deagglomeration tube 220. In some embodiments, the fluid delivery lumen 225 and/or delivery spout 230 may be formed from a perfluoroalkoxy alkane and/or other chemically-resistant polymers. A diameter of the fluid delivery lumen 225 and/or delivery spout 230 may be less than about 0.5 inches, less than or about 0.45 inches, less than or about 0.4 inches, less than or about 0.35 inches, less than or about 0.3 inches, less than or about 0.25 inches, less than or about 0.2 inches, less than or about 0.15 inches, less than or about 0.1 inches, or less. The deagglomeration tube 220 may be formed from a chemically resistant material such as, but not limited to, quartz, perfluoroalkoxy alkane, other polymers and/or other chemically resistant materials.

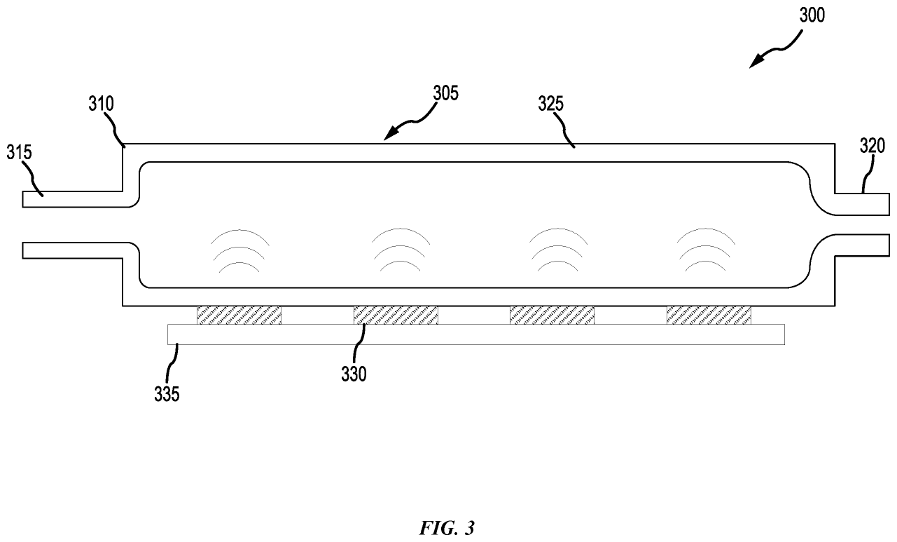

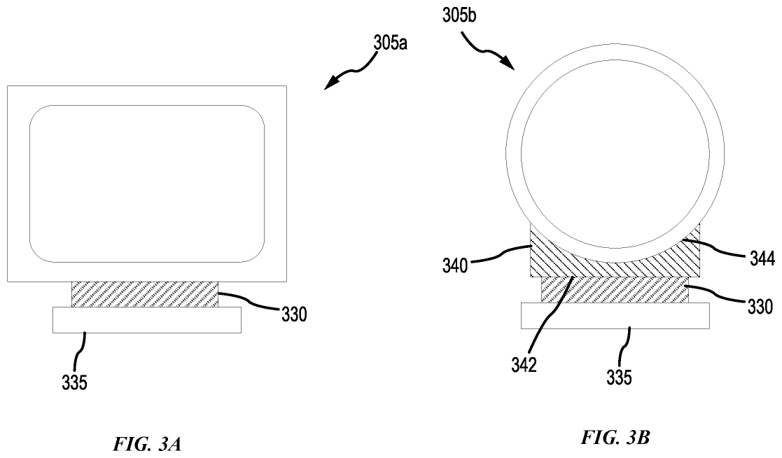

FIG. 3 illustrates a schematic cross-sectional view of an exemplary slurry delivery assembly 300 according to some embodiments of the present technology. FIG. 3 may illustrate further details relating to components in assembly 200, such as for deagglomeration tube 220. Assembly 300 is understood to include any feature or aspect of assembly 200 discussed previously in some embodiments. The assembly 300 may be used to deliver abrasive polishing slurry to a polishing pad, such as polishing pads 110 and 205 described herein. Assembly 300 may show a partial view of the components being discussed and that may be incorporated in a polishing system, similar to polishing system 100 and/or assembly 200. Assembly 300 may include a deagglomeration tube 305, which may be fluidly coupled with a slurry fluid source (not shown). Deagglomeration tube 305 may include a tube body 310 having an inlet 315, an outlet 320, and a medial region 325 that is disposed between the inlet 315 and the outlet 320. In some embodiments, the medial region 325 may have a larger diameter than the inlet 315 and/or outlet 320. For example, in some embodiments, the inlet 315 and/or outlet 320 may have a diameter and/or width of less than or about 1 inch, less than or about 0.75 inches, less than or about 0.5 inches, less than or about 0.375 inches, less than or about 0.25 inches, less than or about 0.125 inches, or less. The inlet 315 and/or outlet 320 may be the same size or may be different. The medial region 325 may have a diameter and/or width of between or about 1 inch and 3 inches, between or about 1.25 inches and 2.75 inches, between or about 1.5 inches and 2.5 inches, between or about 1.75 inches and 2.25 inches, or about 2 inches. The medial region 325 may have a length of between or about 2 inches an 6 inches, between or about 2.5 inches and 5.5 inches, between or about 3 inches and 5 inches, between or about 3.5 inches and 4.5 inches, or about 4 inches. This increase in cross-sectional size may enable polishing slurry that is flowed into the deagglomeration tube 305 to be slowed down as the polishing slurry enters the medial region 325, which may increase the amount of time the polishing slurry is deagglomerated using ultrasonic waves. In some embodiments, an end of the medial region 325 proximate the outlet 320 may be generally funnel-shaped and/or otherwise tapered to prevent any polishing slurry from building up and/or otherwise collecting within corners of the deagglomeration tube 305. Similarly, other internal corners may be rounded, which may help enable the polishing slurry to flow consistently through the deagglomeration tube 305.

In some embodiments, the inlet 315 and/or outlet 320 may be coupled with a fluid delivery lumen (such as fluid delivery lumen 225), which may couple the inlet 315 with a slurry source and/or may couple the outlet 320 with (and/or serve as) a delivery spout. In some embodiments, the outlet 320 may serve as the delivery spout. In such embodiments, the outlet 320 may be bent and/or angled to direct deagglomerated polishing slurry onto a desired location on a polishing pad.

Assembly 300 may include a number of ultrasonic transducers 330 that are coupled with the deagglomeration tube 305. For example, the ultrasonic transducers 330 may be mounted on a baseplate 335 that may include one or more wires and/or electrical contacts to supply electrical power to the ultrasonic transducers 330. In some embodiments, each ultrasonic transducer 330 may include a dedicated baseplate 335, while in other embodiments some or all of the ultrasonic transducers may be mounted on a single baseplate 335. The ultrasonic transducers 330 may include piezoelectric transducers, capacitive transducers, and/or other transducers that may convert electrical power into high frequency waves. While referred to as ultrasonic transducers, it will be appreciated that megasonic frequencies may be utilized in some embodiments. For example, the ultrasonic transducers 330 may emit sound waves in frequencies ranging between about 20 kHz and 2 MHz. The frequency of the waves may be selected based on a composition of the polishing slurry. In some embodiments, higher frequencies, such as those between about 0.8 MHz and 2 MHz, may cause gentler cavitation than lower frequencies. A frequency that is too low may prevent the abrasive particles from being sufficiently deagglomerated, while a frequency that is too high may cause the polishing slurry to boil and/or otherwise become too energized, which may lead to leaks and/or other issues. These sound waves may be directed toward an interior of the deagglomeration tube 305 to deagglomerate and/or otherwise break up any large particles within the polishing slurry. For example, the ultrasonic transducers 330 may be positioned directly and/or indirectly against an outer surface of the medial region 325 of the deagglomeration tube 305. The ultrasonic transducers 330 may be positioned on one or more sides of the medial region 325 of the deagglomeration tube 305. For example, while shown here with ultrasonic transducers 330 positioned against a bottom surface of the medial region 325, ultrasonic transducers 330 may also, or alternatively, be positioned against a top surface, one or more lateral side surfaces, and/or other surfaces of the deagglomeration tube 305. Positioning at least some of the ultrasonic transducers 330 against the bottom surface may ensure that any heavier, large particles are directly agitated by the ultrasonic waves prior to being delivered to the polishing pad.

A number of ultrasonic sensors 330 may be positioned along all or a portion of a length of the deagglomeration tube 305. For example, the deagglomeration tube 305 may include at least or about one ultrasonic transducer, at least or about two ultrasonic transducers, at least or about three ultrasonic transducers, at least or about four ultrasonic transducers, at least or about five ultrasonic transducers, at least or about six ultrasonic transducers, at least or about seven ultrasonic transducers, at least or about eight ultrasonic transducers, at least or about nine ultrasonic transducers, at least or about ten ultrasonic transducers, at least or about fifteen ultrasonic transducers, at least or about twenty ultrasonic transducers, or more. The ultrasonic transducers 330 may be spaced apart along one or more sides of the deagglomeration tube 305 at regular and/or irregular intervals.

The deagglomeration tube 305 may have any cross-sectional shape. For example, some deagglomeration tubes 305a may have rectangular cross-sectional shapes as shown in FIG. 3A. In such embodiments, the ultrasonic transducers 330 may be positioned directly against an outer surface of the deagglomeration tube 305a. In other embodiments, the ultrasonic transducers 330 may include an adapter that is interposed between the ultrasonic transducer 330 and the deagglomeration tube 305. This may be particularly useful in embodiments in which the deagglomeration tube 305b has a generally circular cross-section as shown in FIG. 3B. For example, an adapter 340 may be disposed between the outer surface of the deagglomeration tube 305 and the ultrasonic transducer 330. The adapter 340 may include a flat outer surface 342 that may receive and/or otherwise be positioned against one or more ultrasonic transducers 330. The adapter 340 may include an arcuate inner surface 344 that may be interfaced about the round outer surface of the deagglomeration tube 305. The adapter 340 may enable generally planar ultrasonic transducers 330 to be coupled with a round deagglomeration tube 305b such that larger particles within the polishing slurry may be deagglomerated by waves produced by the ultrasonic transducers 330. In some embodiments, each ultrasonic transducer 330 may include a dedicated adapter 340, while in other embodiments some or all of the ultrasonic transducers may be mounted on a single adapter 340. The adapter 340 may be a metal and/or other material that may adequately transmit vibration from the ultrasonic waves to the surface of the deagglomeration tube 305b. In other embodiments, the ultrasonic transducer 330 may be coupled tangentially to a rounded deagglomeration tube 305b and/or the ultrasonic transducer 330 may include a curved surface.

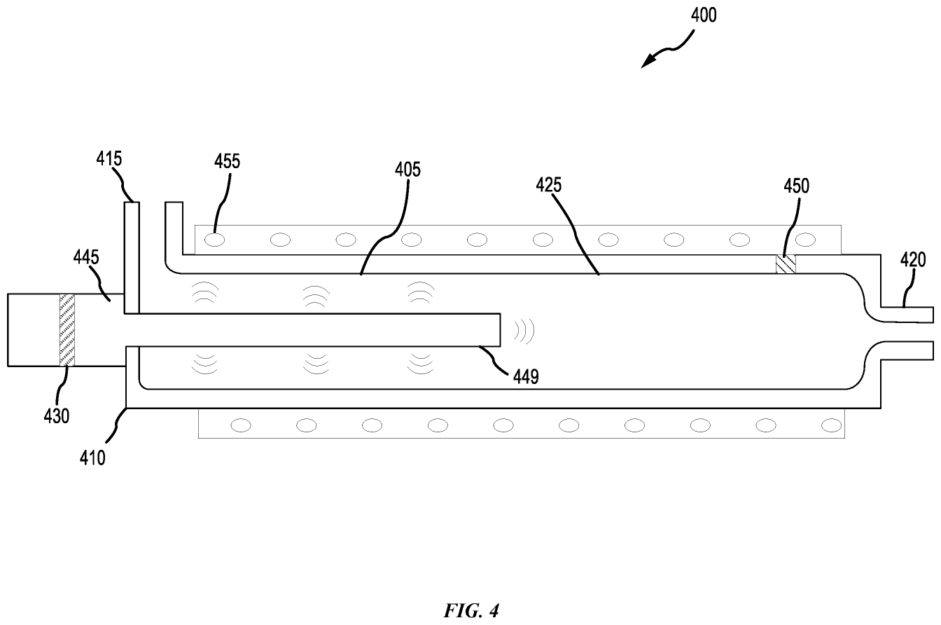

FIG. 4 illustrates a schematic cross-sectional view of an exemplary slurry delivery assembly 400 according to some embodiments of the present technology. FIG. 4 may illustrate further details relating to components in assembly 200 or 300, such as for deagglomeration tube 220 or 305. Assembly 400 is understood to include any feature or aspect of assembly 200 or 300 discussed previously in some embodiments. The assembly 400 may be used to deliver abrasive polishing slurry to a polishing pad, such as polishing pads 110 and 205 described herein. Assembly 400 may show a partial view of the components being discussed and that may be incorporated in a polishing system, similar to polishing system 100 and/or assemblies 200 and 300. Assembly 400 may include a deagglomeration tube 405, which may be fluidly coupled with a slurry fluid source (not shown). Deagglomeration tube 405 may include a tube body 410 having an inlet 415, an outlet 420, and a medial region 425 that is disposed between the inlet 415 and the outlet 420. In some embodiments, the medial region 425 may have a larger diameter than the inlet 415 and/or outlet 420. In some embodiments, the inlet 415 and/or outlet 420 may be positioned along a central axis of the medial region 425. In other embodiments, one or both of the inlet 415 and the outlet 420 may be offset and/or angled relative to a central axis of the medial region 425. For example, as illustrated, the inlet 415 may be generally orthogonal (or at another angle) relative to the central axis of the medial region 425. The inlet 415 may be positioned at or proximate an end of the medial region 425 that is opposite the outlet 420. While shown here with the inlet 415 being formed at a top of the medial region 425, in various embodiments the inlet 415 may be formed on a bottom surface and/or side of the medial region 425. In some embodiments, an end of the medial region 425 proximate the outlet 420 may be generally funnel-shaped and/or otherwise tapered to prevent any polishing slurry from building up and/or otherwise collecting within corners of the deagglomeration tube 405. Similarly, other internal corners may be rounded, which may help enable the polishing slurry to flow consistently through the deagglomeration tube 405.

Assembly 400 may include a number of ultrasonic transducers 430 that are coupled with the deagglomeration tube 405. For example, one or more ultrasonic transducers 430 may be mounted on and/or otherwise coupled with a wave transmission rod 445. Wave transmission rod 445 may have a proximal end that is coupled with the ultrasonic transducers 430 on an outside of the deagglomeration tube 405. A distal end 449 of the wave transmission rod 445 may protrude into an interior of the medial region 425 of the deagglomeration tube 405. This may enable the ultrasonic waves generated from the ultrasonic transducers 430 to be propagated through the interior of the medial region 425 via the wave transmission rode 445 to help break up large particles that may have formed within the abrasive slurry. The waves may be propagated outward from the wave transmission rod 445 in directions that are transverse or otherwise angled relative to a longitudinal axis of the wave transmission rod 445 and/or generally along a length of the medial region 325 through the distal end 449 of the wave transmission rod 445. The wave transmission rod 445 may extend along at least or about 5% of a length of the medial region 425, at least or about 10% of the length of the medial region 425, at least or about 20% of the length of the medial region 425, at least or about 30% of the length of the medial region 425, at least or about 40% of the length of the medial region 425, at least or about 50% of the length of the medial region 425, at least or about 60% of the length of the medial region 425, at least or about 70% of the length of the medial region 425, at least or about 80% of the length of the medial region 425, at least or about 90% of the length of the medial region 425, or more. In some embodiments, the outlet 420 of the deagglomeration tube 405 may be offset from the wave transmission rod 445. This may be particularly useful in embodiments in which the wave transmission rod 445 extends along a substantial length of the medial region 425, as such positioning of the outlet 420 may provide additional clearance for the polishing slurry to flow into the outlet 420. The wave transmission rod 445 may be formed from quartz, a metal coated with a non-reactive material, and/or other chemically resistant material.

In some embodiments, it may be useful to monitor a temperature of the polishing slurry and/or deagglomeration tube 405 to ensure that the polishing slurry is warm enough to be properly flowable and not so hot that the polishing slurry boils or otherwise becomes unsuitable for use in polishing operations. Assembly 400 may include one or more temperature sensors 450, such as thermocouples, which may be used to monitor a temperature of the deagglomeration tube 405 and/or polishing slurry. The temperature sensors 450 may be coupled with the deagglomeration tube 405, such as with the medial region 425 of the deagglomeration tube 405. In some embodiments, the temperature sensors 450 may be positioned against an outer surface of the deagglomeration tube 405, while in other embodiments, at least a portion of a temperature sensor 450 may be disposed within an interior of the deagglomeration tube 405, such as within the medial region 425. For example, the entire temperature sensor 450 may be positioned within the interior of the deagglomeration tube 405 and/or a portion of the temperature sensor 450 may protrude through all or a part of the thickness of the deagglomeration tube 405. This may enable the temperature sensor 450 to come into contact with the polishing slurry to provide an accurate reading of the temperature.

Assembly 400 may include one or more temperature control mechanisms 455 that may be used to maintain a temperature of the deagglomeration tube 405 and/or polishing slurry within a desired temperature range. The temperature control mechanisms 455 may include heating and/or cooling devices. Heating devices may include, without limitation, electric heating coils, heated fluid channels, hot air blowers, and/or other heating mechanisms. Cooling devices may include coolant channels, cool air fans, and/or other cooling mechanism. The temperature control mechanisms 455 may be positioned against and/or otherwise be proximate the deagglomeration tube 405. For example, heating and/or cooling coils/channels may be positioned against and/or around one or more sides of the outer surface of the deagglomeration tube 405. The coils/channels may extend along all or a portion of the length of the deagglomeration tube 405 in various embodiments. In some embodiments, the coils/channels may wrap completely around a periphery of the deagglomeration tube 405. Blowers/fans may be positioned proximate the deagglomeration tube 405 and may be oriented to direct air onto and/or around the deagglomeration tube 405. In some embodiments, one or more temperature control mechanisms 455 may be positioned within an interior of the deagglomeration tube 405. The temperature control mechanisms 455 may operate in conjunction with the temperature sensors 450 to maintain the polishing slurry and/or deagglomeration tube 405 within a predefined temperature range, such as between or about 5° C. and 50° C., between or about 10° C. and 45° C., between or about 15° C. and 40° C., between or about 20° C. and 35° C., or between or about 25° C. and 30° C. For example, if the temperature of the deagglomeration tube 405 and/or slurry drops below and/or approaches a lower threshold, one or more heating devices may be actuated (or adjusted), while one or more cooling devices may be actuated (or adjusted) if the temperature exceeds and/or approaches an upper temperature threshold. Such operation may ensure that the polishing slurry is suitable for polishing operations when the polishing slurry is dispensed from the delivery spout. The temperature of the deagglomeration tube 405 may be correlated with a temperature of the polishing slurry, which may enable the temperature of the polishing slurry to be determined by sampling the temperature of the deagglomeration tube 405 in some embodiments.

By positioning ultrasonic transducers proximate and/or within a deagglomeration tube, embodiments of the present invention may deliver ultrasonic waves to a polishing slurry that deagglomerate and/or otherwise break up large particles within a polishing slurry prior to delivering the polishing slurry to a polishing pad. Embodiments may also include temperature control feedback loops that ensure that the polishing slurry is maintained within desired operating parameters. The delivery of acceptable polishing slurry may enable polishing operations to be conducted with better results, and with minimal to no scratching of the film.

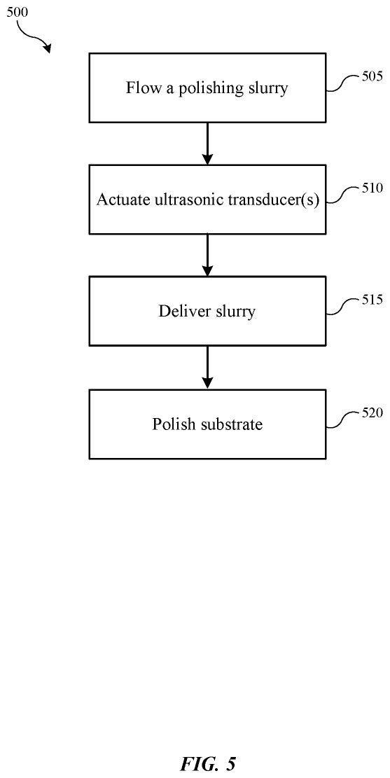

FIG. 5 shows exemplary operations in a method 500 for polishing a substrate according to some embodiments of the present technology. Method 500 may be performed using a slurry delivery assembly, such as slurry delivery assembly 200, 300, or 400 described herein. Method 500 may include operations prior to the substrate polishing in some embodiments. For example, prior to the polishing, a substrate may have one or more deposition and/or etching operations performed as well as any planarization or other process operations performed. Method 500 may include a number of operations that may be performed automatically within a system to limit manual interaction, and to provide increased efficiency and precision over manual operations. Method 500 may be performed in conjunction with a conventional CMP polishing process.

Method 500 may include flowing a polishing slurry into a deagglomeration tube at operation 505. The polishing slurry may include a nano-sized abrasive powder dispersed in a chemically reactive solution that may help polish and/or planarize a substrate film surface. One or more ultrasonic transducers that are coupled with the deagglomeration tube may be actuated while the polishing slurry is flowed through the deagglomeration tube at operation 510. For example, an electric current may be supplied to the ultrasonic transducers that the ultrasonic transducers convert to sound waves. These sound waves may be emitted by the ultrasonic transducers and directed toward the deagglomeration tube, where the sound waves may vibrate and break up any large particles that have formed within the polishing slurry. Oftentimes, the sound waves may be between about 10 kHz and 20 MHz, although other frequencies may be utilized in various embodiments. The polishing slurry may be delivered to a polishing pad at operation 515. For example, the polishing slurry may be flowed through an outlet of the deagglomeration tube and through a delivery spout that expels the polishing slurry on a top surface of the polishing pad. The polishing slurry may be delivered to polishing pad continuously and/or periodically during the polishing operation.

At operation 520, a substrate atop the polishing pad may be polished. For example, the substrate may be positioned face (film side) down on a carrier, which may rotate and/or laterally translate the face of the substrate against the polishing pad. The chemical solution of the slurry may chemically etch and soften the film while the abrasive particles mechanically abrade and/or otherwise remove a portion of the film to planarize and/or otherwise alter a surface of the substrate.

In some embodiments, the method 500 may include monitoring a temperature of the polishing slurry and/or the deagglomeration tube. The temperature may be monitored using one or more temperature sensors, such as thermocouples, that may be positioned against, proximate, and/or within the deagglomeration tube. One or more temperature control mechanisms, such as heating and/or cooling devices, may be operated alone or in conjunction with the temperature sensors to maintain a desired temperature of the deagglomeration tube and/or polishing slurry. For example, when the temperature of the deagglomeration tube and/or polishing slurry is below and/or approaching a lower threshold, the deagglomeration tube and/or polishing slurry may be heated. When the temperature of the deagglomeration tube and/or polishing slurry is above and/or approaching an upper threshold, the deagglomeration tube and/or polishing slurry may be cooled. This may ensure that the polishing slurry is maintained at optimal temperatures prior to being delivered to the polishing pad and may result in more effective polishing operations.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A slurry delivery assembly, comprising:
a slurry fluid source;
a flurry delivery lumen having a lumen inlet and a lumen outlet, the lumen inlet being fluidly coupled with an output of the slurry fluid source;
a deagglomeration tube fluidly coupled with the lumen outlet, the deagglomeration tube comprising a tube inlet and a tube outlet; and
one or more ultrasonic transducers coupled with the deagglomeration tube.

2. The slurry delivery assembly of claim 1, wherein:
the one or more ultrasonic transducers comprise piezoelectric transducers.

3. The slurry delivery assembly of claim 1, wherein:
the one or more ultrasonic transducers are positioned against an outer surface of the deagglomeration tube.

4. The slurry delivery assembly of claim 3, further comprising:
an adapter interposed between the outer surface of the deagglomeration tube and the one or more ultrasonic transducers.

5. The slurry delivery assembly of claim 1, wherein:
the one or more ultrasonic transducers are spaced apart evenly along length of deagglomeration tube.

6. The slurry delivery assembly of claim 1, wherein:
the one or more ultrasonic transducers are positioned on multiple sides of the deagglomeration tube.

7. The slurry delivery assembly of claim 1, further comprising:
a support arm that is coupled with the deagglomeration tube.

8. The slurry delivery assembly of claim 1, wherein:
an internal end of the deagglomeration tube proximate the tube outlet is funnel-shaped.

9. A slurry delivery assembly, comprising:
a deagglomeration tube comprising:
an inlet;
an outlet; and
a medial region disposed between the inlet and the outlet, the medial region having a greater diameter than the inlet and the outlet; and
one or more ultrasonic transducers coupled with the deagglomeration tube.

10. The slurry delivery assembly of claim 9, further comprising:
a wave transmission rod having a proximal end and a distal end, the proximal end being coupled with the one or more ultrasonic transducers and the distal end protruding into an interior of the medial region of the deagglomeration tube.

11. The slurry delivery assembly of claim 10, wherein:
the wave transmission rod extends at least partially along a length of the medial region of the deagglomeration tube.

12. The slurry delivery assembly of claim 9, further comprising:
a temperature control mechanism disposed proximate the deagglomeration tube.

13. The slurry delivery assembly of claim 12, wherein:
the temperature control mechanism comprises one or both of a heating device and a cooling device.

14. The slurry delivery assembly of claim 9, further comprising:
a thermocouple that is coupled with the medial region of the deagglomeration tube.

15. The slurry delivery assembly of claim 14, wherein:
the thermocouple is disposed within an interior of the medial region of the deagglomeration tube.

16. The slurry delivery assembly of claim 9, further comprising:
a delivery spout coupled with the outlet.

17. A method of polishing a substrate, comprising:
flowing a polishing slurry into a deagglomeration tube;
actuating one or more ultrasonic transducers that are coupled with the deagglomeration tube while the polishing slurry is flowed through the deagglomeration tube;
delivering the polishing slurry to a polishing pad; and
polishing a substrate atop the polishing pad.

18. The method of polishing a substrate of claim 17, further comprising:
monitoring a temperature of one or both of the deagglomeration tube and the polishing slurry.

19. The method of polishing a substrate of claim 18, further comprising:
adjusting a temperature control mechanism positioned proximate the deagglomeration tube based on the temperature.

20. The method of polishing a substrate of claim 17, wherein:
the deagglomeration tube comprises quartz.
